(19) United States
(12) Patent Application Publication
(10) Pub. No.: US 2008/0073686 A1
(43) Pub. Date: Mar. 27, 2008

(54) Thin-Film Transistor Array and Method for Manufacturing the Same

(75) Inventor: Chien-Chung Kuo, Taichung County (TW)

Correspondence Address: WPAT, PC, 7225 BEVERLY ST., ANNANDALE, VA, 22003, US

(73) Assignee: WINTEK CORPORATION, Taichung (TW)

(21) Appl. No.: 11/682,286

(22) Filed: Mar. 5, 2007

(30) Foreign Application Priority Data
Sep. 22, 2006 (TW) 095135131

(51) Int. Cl. H01L 29/94

(52) U.S. Cl. 257/296

(57) ABSTRACT

A thin-film transistor (TFT) array and a method for manufacturing the same, disposing a storage capacitor in a data-line region so that the storage capacitor does not occupy any area of a pixel region so as to increase the aperture ratio. The thin-film transistor array comprises a first conductive layer, an insulating layer, a semiconductor layer, a doped semiconductor layer, a top transparent electrode, a second conductive layer and a passivation layer formed in turn on a substrate so that the thin-film transistor array comprises a plurality of pixels, each pixel comprising a thin-film transistor, a scanning line, a data line, a storage capacitor, and a pixel electrode.

### BACKGROUND OF THE INVENTION

1. Field of the Invention

The present invention generally relates to a thin-film transistor (TFT) array and a method for manufacturing the same and, more particularly, to a thin-film transistor array and a method for manufacturing the thin-film transistor array disposing a storage capacitor in a data-line region so that the storage capacitor does not occupy any area of a pixel region so as to increase the aperture ratio.

2. Description of the Prior Art

In recent years, the thin, light and radiation-free flat panel displays (FDPs) have been dominant in the display industry. More particularly, liquid crystal displays (LCDs) using thin-film transistors, referred to as TFT-LCDs, have become the most popular one due to the higher resolution and wider applications for various panel sizes.

Please refer to FIG. 1, which is a conventional TFT structure of a TFT-LCD using five masks. To begin with, a first conductive layer 102 is deposited on a substrate 101 and then patterned as a gate electrode using the first mask. A gate insulating layer 103, a semiconductor layer 104 and an n-type semiconductor layer 105 are deposited in order. The semiconductor layer 104 and the n-type semiconductor layer 105 are then patterned using the second mask. A second semiconductor layer 106 is deposited and patterned by the third mask so as to form a drain electrode and a source electrode. Also, back channel etching (BCE) is used to remove the n-type semiconductor layer 105 on the gate electrode. A passivation layer 107 is deposited and then the fourth mask is used to form a contact hole 108 in the passivation layer 107. At last, an ITO transparent electrode 109 is deposited and patterned using the fifth mask. A TFT array can be manufactured using the five masks so as to control the pixels on the LCD.

In FIG. 1, a storage capacitor 110 for the TFT is composed of the first conductive layer 102, the gate insulating layer 103, the passivation layer 107 and the transparent electrode 109. The storage capacitor (Cs) 110 holds the charged voltage until a next frame arrives.

The storage capacitor (Cs) 110 is either “Cs on gate” or “Cs on common”, as shown in FIG. 2A and FIG. 2B, respectively. The layout of the storage capacitors includes capacitor electrodes and the wiring between the capacitor electrodes corresponding to each pixel. The gate wiring in the case of “Cs on gate” functions as the wiring between the capacitor electrodes, the pixel having “Cs on gate” exhibits a higher aperture ratio than the pixel having “Cs on common”.

However, in FIG. 2A and FIG. 2B, since a storage capacitor comprises two dielectric layers, the storage capacitor having “Cs on gate” or “Cs on common” is disposed in a region enclosed by the scanning lines 112 and the data lines 113 so as to store enough electric charge. Such a structure for the storage capacitor 110 occupies a great amount of area in the pixel region 114 and thus it leads to a lowered aperture ratio.

In order to improve the aperture ratio, U.S. Pat. No. 6,262,784 discloses an active matrix display devices that uses a first conductive layer, a pixel electrode and a dielectric layer sandwiched between the first conductive layer and the pixel electrode so as to form a storage capacitor. On the other hand, in order to reduce the parasitic capacitance, the layout of a storage capacitor in U.S. Pat. No. 6,115,089 is designed. However, the storage capacitor in U.S. Pat. No. 6,115,089 still occupies a certain amount of area of the pixel region, which leads to a limited aperture ratio.

Therefore, there is need in providing thin-film transistor array and a method for manufacturing the thin-film transistor array disposing a storage capacitor in a data-line region so that the storage capacitor does not occupy any area of a pixel region so as to increase the aperture ratio. Moreover, in the method for manufacturing the thin-film transistor array, a thickened flat layer is employed so as to reduce the parasitic capacitance.

### SUMMARY OF THE INVENTION

It is a primary object of the present invention to provide a thin-film transistor array and a method for manufacturing the thin-film transistor array, disposing a storage capacitor in a data-line region so as to increase the aperture ratio.

It is a secondary object of the present invention to provide a thin-film transistor array and a method for manufacturing the thin-film transistor array, using a thickened flat layer so as to reduce the parasitic capacitance.

In order to achieve the foregoing objects, the present invention provides a thin-film transistor (TFT) array, comprising a first conductive layer, an insulating layer, a semiconductor layer, a doped semiconductor layer, a top transparent electrode, a flat layer, a second conductive layer and a passivation layer formed in turn on a substrate so that the thin-film transistor array comprises a plurality of pixels, each pixel comprising: a thin-film transistor, using the first conductive layer for a gate electrode and the second conductive layer for a source electrode and a drain electrode of the thin-film transistor; a scanning line, electrically coupled to the gate electrode of the thin-film transistor; a data line, electrically coupled to the source/drain electrode of the thin-film transistor; a storage capacitor, formed of the first conductive layer, the insulating layer, and the top transparent electrode, the storage capacitor being partially overlapped with the data line, wherein the top transparent electrode is used as a top electrode of the storage capacitor and the first conductive layer is used as a bottom electrode of the storage capacitor, wherein the storage capacitor is electrically coupled to the source/drain electrode of the thin-film transistor by way of the top transparent electrode; and a pixel electrode, being electrically coupled to the source/drain electrode of the thin-film transistor by way of the top transparent electrode.

The present invention further provides a method for manufacturing a thin-film transistor (TFT) array, comprising steps of: forming a first conductive layer on a substrate so as to define a TFT region, a scanning line region, a data line region and a storage capacitor region, wherein the first conductive layer is used as a gate electrode of a thin-film transistor and a bottom electrode of a storage capacitor, wherein the storage capacitor region is partially overlapped with the data line region; forming an insulating layer, a semiconductor layer and a doped semiconductor layer in turn on the first conductive layer and removing the semiconductor layer and the doped semiconductor layer outside the TFT region; defining a top transparent electrode on the doped semiconductor layer and the insulating layer uncovered with the doped semiconductor layer so that the top transparent electrode is used as a pixel electrode and a top electrode of the storage capacitor; forming a patterned flat layer on the top electrode of the storage capacitor, the scanning line region and the data line region; forming a patterned second conductive layer on the patterned flat layer and the top transparent electrode so that the patterned second conductive layer is used as a drain electrode and a source electrode of the thin-film transistor; removing the top transparent electrode, the doped semiconductor layer and part of the semiconductor layer on the gate electrode in turn by etching; and forming a patterned passivation layer.

In one embodiment, the first conductive layer comprises a gate metal layer and a bottom transparent electrode formed on the gate metal layer. Preferably, the gate metal layer comprises at least one of chromium (Cr), molybdenum (Mo), aluminum (Al), tantalum (Ta) and combination thereof. Preferably, the bottom transparent electrode comprises at least one of indium tin oxide (ITO) and indium zinc oxide (IZO). Preferably, the insulating layer comprises at least one of silicon oxide, silicon nitride and silicon oxy-nitride. Preferably, the semiconductor layer is an amorphous silicon layer. Preferably, the doped semiconductor layer is an n-type amorphous silicon layer. Preferably, the top transparent electrode comprises at least one of indium tin oxide (ITO) and indium zinc oxide (IZO). Preferably, the flat layer comprises at least an organic polymer material. Preferably, the second conductive layer comprises at least one of chromium (Cr), aluminum (Al) and combination thereof. Preferably, the passivation layer comprises at least one of silicon oxide, silicon nitride and silicon oxy-nitride.

### BRIEF DESCRIPTION OF THE DRAWINGS

The objects, spirits and advantages of the preferred embodiments of the present invention will be readily understood by the accompanying drawings and detailed descriptions, wherein:

FIG. 1A is a cross-sectional view of a conventional thin-film transistor;

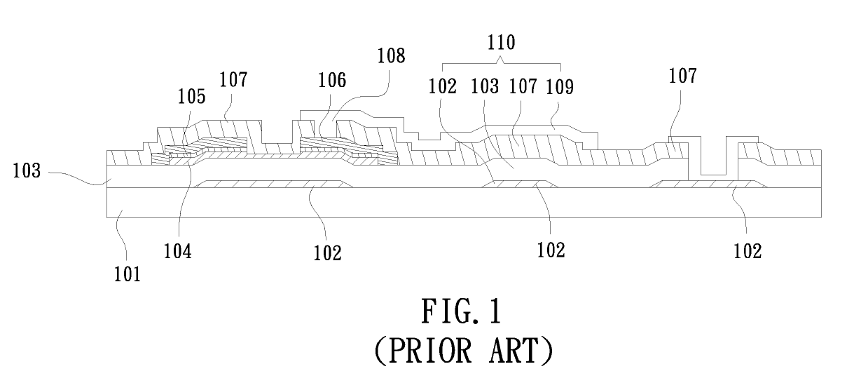

FIG. 2A is a top view of a conventional Cs on gate;

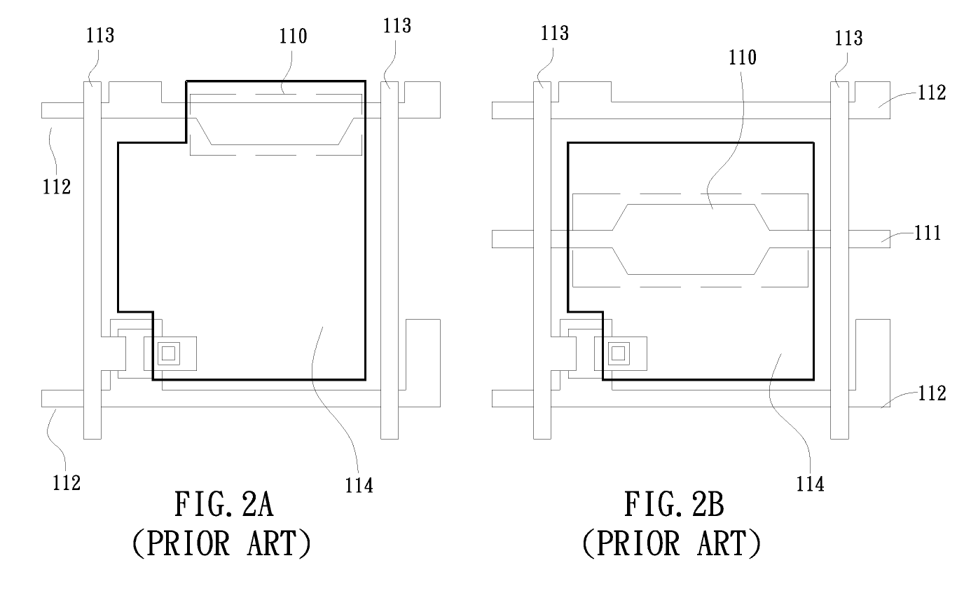

FIG. 2B is a top view of a conventional Cs on common;

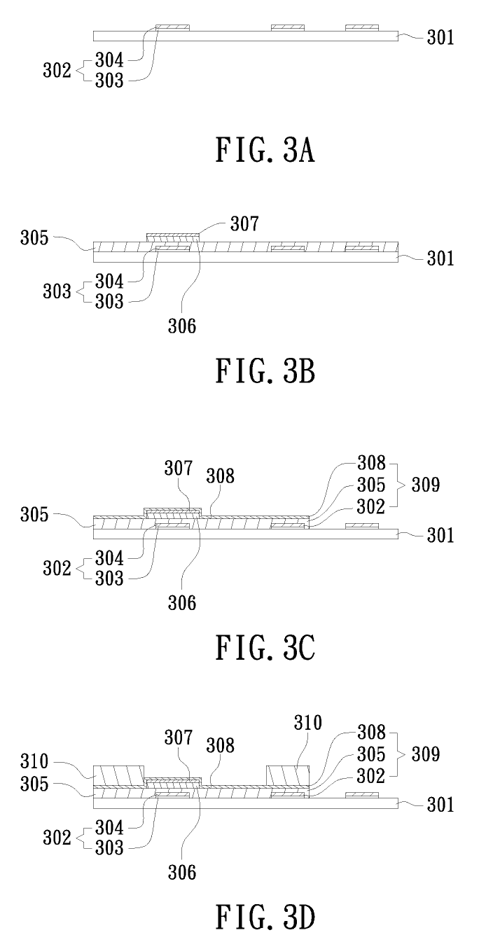

FIG. 3A to FIG. 3G are cross-sectional views showing the formation of a thin-film transistor array according to the present invention;

FIG. 4 is a top view of a thin-film transistor array according to one preferred embodiment of the present invention; and

FIG. 5 is a top view of a thin-film transistor array according to another preferred embodiment of the present invention.

### DETAILED DESCRIPTION OF THE PREFERRED EMBODIMENT

The present invention providing a method for manufacturing pixels for displays and organic electronic devices can be exemplified by the preferred embodiments as described hereinafter.

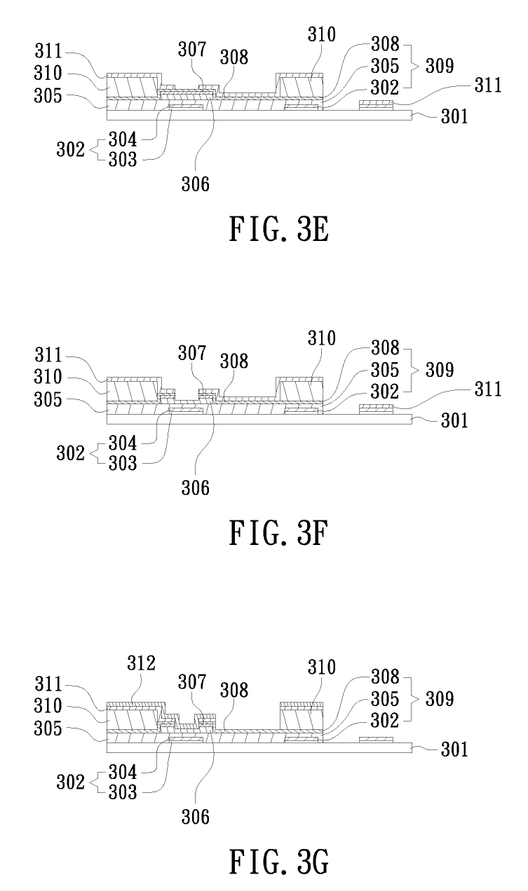

Please refer to FIG. 3A and FIG. 3G for cross-sectional views showing the formation of a thin-film transistor array according to the present invention. To begin with, in FIG. 3A, a first conductive layer 302 is deposited on a substrate 301 and is patterned using a first mask so as to define a TFT region, a scanning line region (not shown), a data line region (not shown) and a storage capacitor region. The first conductive layer is used as a gate electrode of a thin-film transistor and a bottom electrode of a storage capacitor. In the present invention, the storage capacitor region is partially overlapped with the data line region. Preferably, the first conductive layer 302 comprises a gate metal layer 303 and a bottom transparent electrode 304 formed on the gate metal layer 303. In this case, the bottom transparent electrode 304 protects the first conductive layer 302 from being etched when a second conductive layer 311 (in FIG. 3E) is being selectively etched. Otherwise, the first conductive layer 302 cannot comprise any material that is etchable in the solution for etching the second conductive layer 311. In the present embodiment, the gate metal layer 303 comprises at least one of chromium (Cr), molybdenum (Mo), aluminum (Al), tantalum (Ta) and combination thereof. In the present embodiment, the bottom transparent electrode 304 comprises at least one of indium tin oxide (ITO) and indium zinc oxide (IZO).

As shown in FIG. 3B, an insulating layer 305, an semiconductor layer 306 and an n-type semiconductor layer 307 are formed in turn on the first conductive layer 302. Then, a second mask is used to pattern the semiconductor layer 306 and the n-type semiconductor layer 307 so that the semiconductor layer 306 and the n-type semiconductor layer 307 are only formed on the gate electrode of the thin-film transistor. In the present embodiment, the insulating layer 305 comprises at least one insulating material such as silicon oxide (SiOₓ), silicon nitride (SiNₓ) and silicon oxy-nitride (SiOₓN_{y}). In the present embodiment, the semiconductor layer 306 is an amorphous silicon layer, and the doped semiconductor layer 307 is an n-type amorphous silicon layer.

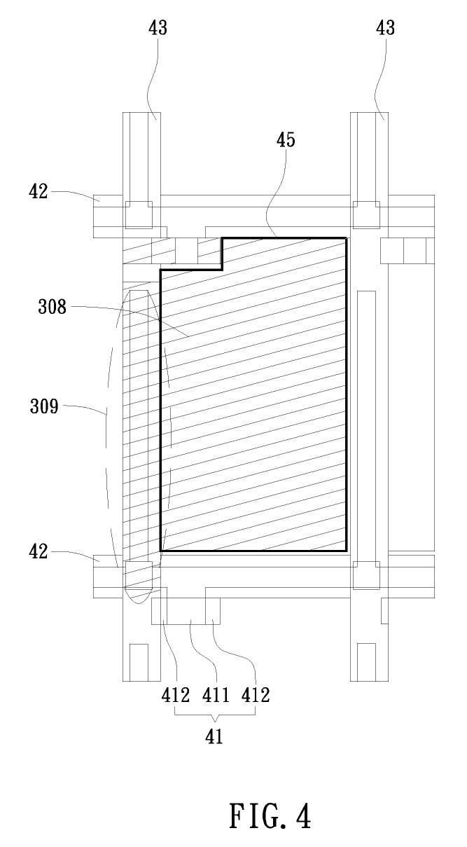

Please refer to FIG. 3C, a top transparent electrode 308 is deposited and patterned using a third mask so that the top transparent electrode 308 covers the doped semiconductor layer 307 and the insulating layer 305 uncovered with the doped semiconductor layer 307. The top transparent electrode 308 is used as a pixel electrode in a pixel region 215 (FIG. 4) and a top electrode of a storage capacitor. In this case, the storage capacitor 309 is formed of the first conductive layer 302, the insulating layer 305 and the top transparent electrode 308. In the present embodiment, the top transparent electrode 308 comprises at least one of indium tin oxide (ITO) and indium zinc oxide (IZO).

Then, as shown in FIG. 3D, a flat layer 310 is deposited and patterned using a fourth mask to cover the top electrode 308 of the storage capacitor 309, the scanning line region (not shown) and the data line region (not shown). The flat layer 310 is thickened so as to reduce the parasitic capacitance. In the present embodiment, the flat layer 310 comprises at least an organic polymer material such as acrylic.

As shown in FIG. 3E, a second conductive layer 311 is deposited and patterned using a fifth mask on the patterned flat layer 310 and the top transparent electrode 308. In the present embodiment, the second conductive layer 311 comprises at least one of chromium (Cr), aluminum (Al) and combination thereof.

Then, in FIG. 3F, the top transparent electrode 308, the n-type semiconductor layer 307 and part of the semiconductor layer 306 on the gate electrode of the TFT are removed in turn by etching so that the patterned second conductive layer 311 is used as a drain electrode and a source electrode of the thin-film transistor.

Finally, in FIG. 3G, a passivation layer 312 is deposited on top of the substrate 301 and patterned using a sixth mask. Moreover, the pixel electrode 308 and the second conductive layer 311 are selectively etched. A thin-film transistor can thus be completed. The passivation layer 312 isolates the thin-film transistor from the atmosphere and/or the moisture so as to enhance the reliability. In the present embodiment, the passivation layer 312 comprises at least one insulating material such as silicon oxide, silicon nitride and silicon oxy-nitride.

Please refer to FIG. 4, which is a top view of a thin-film transistor array according to one preferred embodiment of the present invention. In FIG. 4, the thin-film transistor array of the present invention comprises a plurality of pixels, each pixel comprising: a thin-film transistor 41 using the first conductive layer as a gate electrode 411 and the second conductive layer as a drain electrode and a source electrode 412 of the thin-film transistor 41; a scanning line 42, electrically coupled to the gate electrode 411 of the thin-film transistor 41; a data line 43, electrically coupled to the drain/source electrode 412 of the thin-film transistor 41; a storage capacitor 309, formed of the first conductive layer, the insulating layer and the top transparent electrode 308 (shown as the shadowed part in the figure) on the region of the data line 43; and a pixel electrode, being electrically coupled to the source/drain electrode 412 of the thin-film transistor 41 by way of the top transparent electrode 308. The top transparent electrode 308 is used as a top electrode of the storage capacitor 309 and the first conductive layer is used as a bottom electrode of the storage capacitor 309. The storage capacitor 309 is electrically coupled to the source/drain electrode 412 of the thin-film transistor 41 by way of the top transparent electrode 308 so as to hold a charged voltage of a pixel corresponding to the thin-film transistor 41. The pixel region 45 is defined as part of the top transparent electrode 308 that is not overlapped with the thin-film transistor 41, the scanning line 42, the data line 43 and the storage capacitor 309. Accordingly, in the present invention, the storage capacitor 309 is disposed in the region of the data line 43 and thus the pixel has a higher aperture ratio compared to conventional arts.

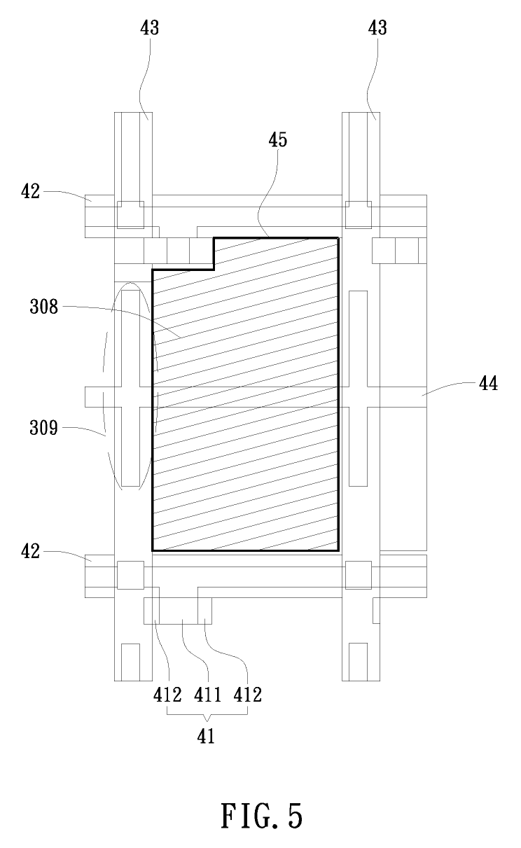

FIG. 5 is a top view of a thin-film transistor array according to another preferred embodiment of the present invention. The thin-film transistor array in FIG. 5 is different from the thin-film transistor array in FIG. 4 that the bottom electrode of the storage capacitor 309 (enclosed by the dotted line) is coupled to the common line 44 instead of the gate line. Even though the pixel in FIG. 5 has a smaller aperture ratio than the pixel in FIG. 4, the aperture ratio of the pixel in FIG. 5 is still larger than the aperture ratio of the pixel in conventional arts because the storage capacitor 309 is disposed in the region of the data line 43.

According to the above discussion, it is apparent that the present invention discloses a thin-film transistor array and a method for manufacturing the thin-film transistor array disposing a storage capacitor in a data-line region so that the storage capacitor does not occupy any area of a pixel region so as to increase the aperture ratio. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A thin-film transistor (TFT) array, comprising a first conductive layer, an insulating layer, a semiconductor layer, a doped semiconductor layer, a top transparent electrode, a second conductive layer and a passivation layer formed in turn on a substrate so that the thin-film transistor array comprises a plurality of pixels, each pixel comprising:
a thin-film transistor, using the first conductive layer for a gate electrode and the second conductive layer for a source electrode and a drain electrode of the thin-film transistor;
a scanning line, electrically coupled to the gate electrode of the thin-film transistor;
a data line, electrically coupled to the source/drain electrode of the thin-film transistor;
a storage capacitor, formed of the first conductive layer, the insulating layer, and the top transparent electrode, the storage capacitor being partially overlapped with the data line, wherein the top transparent electrode is used as a top electrode of the storage capacitor and the first conductive layer is used as a bottom electrode of the storage capacitor, wherein the storage capacitor is electrically coupled to the source/drain electrode of the thin-film transistor by way of the top transparent electrode; and
a pixel electrode, being electrically coupled to the source/drain electrode of the thin-film transistor by way of the top transparent electrode.

2. The thin-film transistor array as recited in claim 1, wherein the first conductive layer comprises a gate metal layer and a bottom transparent electrode formed on the gate metal layer.

3. The thin-film transistor array as recited in claim 2, wherein the gate metal layer comprises at least one of chromium (Cr), molybdenum (Mo), aluminum (Al), tantalum (Ta) and combination thereof.

4. The thin-film transistor array as recited in claim 2, wherein the bottom transparent electrode comprises at least one of indium tin oxide (ITO) and indium zinc oxide (IZO).

5. The thin-film transistor array as recited in claim 1, wherein the insulating layer comprises at least one of silicon oxide, silicon nitride and silicon oxy-nitride.

6. The thin-film transistor array as recited in claim 1, wherein the semiconductor layer is an amorphous silicon layer.

7. The thin-film transistor array as recited in claim 1, wherein the doped semiconductor layer is an n-type amorphous silicon layer.

8. The thin-film transistor array as recited in claim 1, wherein the top transparent electrode comprises at least one of indium tin oxide (ITO) and indium zinc oxide (IZO).

9. The thin-film transistor array as recited in claim 1, wherein the second conductive layer comprises at least one of chromium (Cr), aluminum (Al) and combination thereof.

10. The thin-film transistor array as recited in claim 1, wherein the passivation layer comprises at least one of silicon oxide, silicon nitride and silicon oxy-nitride.

11. A method for manufacturing a thin-film transistor (TFT) array, comprising steps of:
forming a first conductive layer on a substrate so as to define a TFT region, a scanning line region, a data line region and a storage capacitor region, wherein the first conductive layer is used as a gate electrode of a thin-film transistor and a bottom electrode of a storage capacitor, wherein the storage capacitor region is partially overlapped with the data line region;
forming an insulating layer, a semiconductor layer and a doped semiconductor layer in turn on the first conductive layer and removing the semiconductor layer and the doped semiconductor layer outside the TFT region;
defining a top transparent electrode on the doped semiconductor layer and the insulating layer uncovered with the doped semiconductor layer so that the top transparent electrode is used as a pixel electrode and a top electrode of the storage capacitor;
forming a patterned flat layer on the top electrode of the storage capacitor, the scanning line region and the data line region;
forming a patterned second conductive layer on the patterned flat layer and the top transparent electrode so that the patterned second conductive layer is used as a drain electrode and a source electrode of the thin-film transistor and a bottom electrode of the storage capacitor;
removing the top transparent electrode, the doped semiconductor layer and part of the semiconductor layer on the gate electrode in turn by etching; and
forming a patterned passivation layer.

12. The method for manufacturing a thin-film transistor array as recited in claim 11, wherein the first conductive layer comprises a gate metal layer and a bottom transparent electrode formed on the gate metal layer.

13. The method for manufacturing a thin-film transistor array as recited in claim 12, wherein the gate metal layer comprises at least one of chromium (Cr), molybdenum (Mo), aluminum (Al), tantalum (Ta) and combination thereof.

14. The method for manufacturing a thin-film transistor array as recited in claim 12, wherein the bottom transparent electrode comprises at least one of indium tin oxide (ITO) and indium zinc oxide (IZO).

15. The method for manufacturing a thin-film transistor array as recited in claim 11, wherein the insulating layer comprises at least one of silicon oxide, silicon nitride and silicon oxy-nitride.

16. The method for manufacturing a thin-film transistor array as recited in claim 11, wherein the semiconductor layer is an amorphous silicon layer.

17. The method for manufacturing a thin-film transistor array as recited in claim 11, wherein the doped semiconductor layer is an n-type amorphous silicon layer.

18. The method for manufacturing a thin-film transistor array as recited in claim 11, wherein the top transparent electrode comprises at least one of indium tin oxide (ITO) and indium zinc oxide (IZO).

19. The method for manufacturing a thin-film transistor array as recited in claim 11, wherein the flat layer comprises at least an organic polymer material.

20. The method for manufacturing a thin-film transistor array as recited in claim 11, wherein the second conductive layer comprises at least one of chromium (Cr), aluminum (Al) and combination thereof.

21. The method for manufacturing a thin-film transistor array as recited in claim 11, wherein the passivation layer comprises at least one of silicon oxide, silicon nitride and silicon oxy-nitride.
